(19) United States
(12) Patent Application Publication
(10) Pub. No.: US 2023/0335403 A1
(43) Pub. Date: Oct. 19, 2023

(54) METHOD OF MANUFACTURING SEMICONDUCTOR DEVICE

(71) Applicant: NANYA TECHNOLOGY CORPORATION, New Taipei City (TW)

(72) Inventors: Ning-Shuang HSU, Chiayi City (TW); Che-Hsien LIAO, New Taipei City (TW)

(21) Appl. No.: 17/659,014

(22) Filed: Apr. 13, 2022

(51) Int. Cl. H01L 21/285

(52) U.S. Cl. CPC H01L 21/28568

(57) ABSTRACT

A method of manufacturing a semiconductor device includes: depositing a filling material to fill a trench of a substrate, in which the trench has a depth and a width, and a ratio of the depth to the width is equal to or greater than 8, and in which the filling material includes TiN; and annealing the filling material.

### BACKGROUND

### Field of Disclosure

The present disclosure relates to a method of manufacturing a semiconductor device.

### Description of Related Art

Semiconductor industries are developing and improving the manufacturing process for semiconductor structures, while the miniaturization of components continues. The accuracy of the scale and shape of the structure has thus become more important. For instance, a larger aspect ratio of a trench included in a semiconductor structure of a word line is required to reduce its resistivity. To create such a semiconductor structure of word line, tungsten (W) and titanium nitride (TiN) stacks are often used. However, the larger aspect ratio of the trench may cause a poor ability filling a word line structure by using tungsten and titanium nitride stacks. Therefore, a suitable prescription for manufacturing a semiconductor device with satisfying performance is necessary and indispensable.

### SUMMARY

In view of this, one purpose of present disclosure is to provide a method of manufacturing a semiconductor device that can solve the aforementioned problems.

In order to achieve the above objective, according to an embodiment of the present disclosure, a method of manufacturing a semiconductor device includes: depositing a filling material to fill a trench of a substrate, in which the trench has a depth and a width, a ratio of the depth to the width is equal to or greater than 8, and in which the filling material includes TiN; and annealing the filling material.

In one or more embodiments of the present disclosure, the depositing filling material includes: placing the substrate in a chamber; performing a first deposition process using a first process gas in the chamber; and performing a second deposition process using a second process gas in the chamber.

In one or more embodiments of the present disclosure, the first process gas comprises titanium tetrachloride (TiCl₄).

In one or more embodiments of the present disclosure, the second process gas comprises ammonia (NH₃).

In one or more embodiments of the present disclosure, the method further includes: performing a purge process using purge gas in the chamber.

In one or more embodiments of the present disclosure, performing the purge process is after the performing the first deposition process and before the performing the second deposition process.

In one or more embodiments of the present disclosure, the performing the purge process is after performing the second deposition process.

In one or more embodiments of the present disclosure, the purge gas includes hydrogen (H₂) and nitrogen (N₂).

In one or more embodiments of the present disclosure, performing the purge process is before performing the first deposition process.

In one or more embodiments of the present disclosure, the purge gas includes NH₃ and H₂.

In one or more embodiments of the present disclosure, the depositing the filling material entirely fills the trench with the filling material.

In one or more embodiments of the present disclosure, the annealing is performed in a temperature in a range from about 750 to about 1100 Celsius degree.

Accordingly, this method of manufacturing a semiconductor device solves the word line filling problem of the conventional method, so that the semiconductor device has higher quality word lines, thereby reducing resistivity and improving its performance.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a flow chart of a method of manufacturing a semiconductor device in accordance with an embodiment of present disclosure;

FIG. 2 is a flow chart of another method of manufacturing the semiconductor device in accordance with an embodiment of present disclosure;

FIG. 3 is a schematic view of an intermediate stage of manufacturing a semiconductor device in accordance with an embodiment of present disclosure;

FIG. 4 is a schematic view of an intermediate stage of manufacturing the semiconductor device in accordance with an embodiment of present disclosure; and

FIG. 5 is a schematic view of an intermediate stage of manufacturing the semiconductor device in accordance with an embodiment of present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

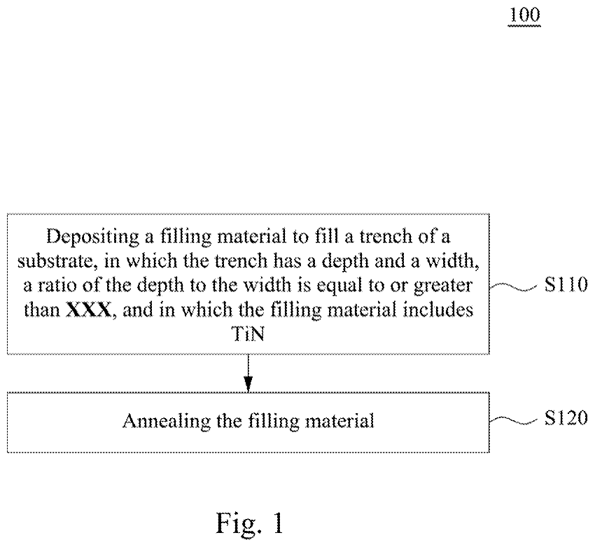

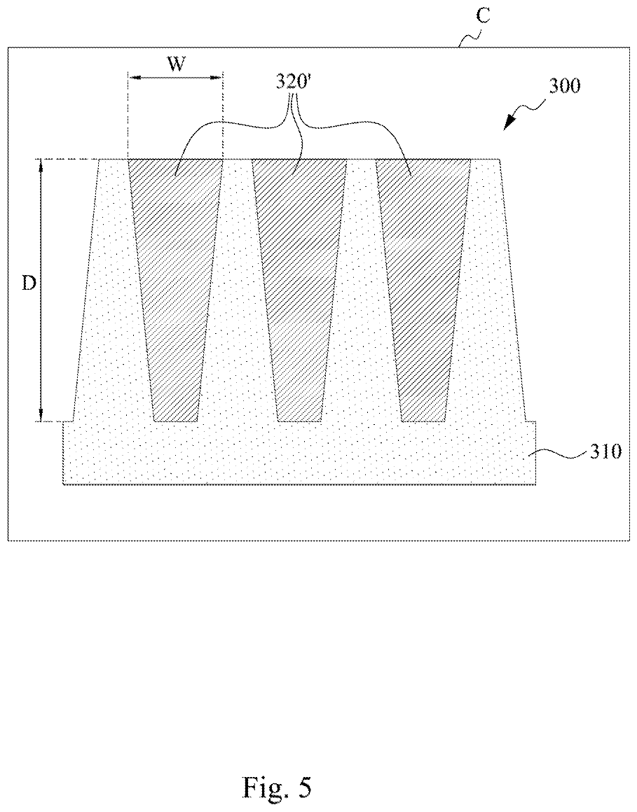

Reference is made to FIG. 1. FIG. 1 is a flow chart of a method 100 of manufacturing a semiconductor device in accordance with an embodiment of present disclosure. The method 100 shown in FIG. 1 includes step S110 and step S120. Please refer to FIGS. 1, 3, and 4 for better understanding step S110, and refer to FIG. 5 for better understanding step S120.

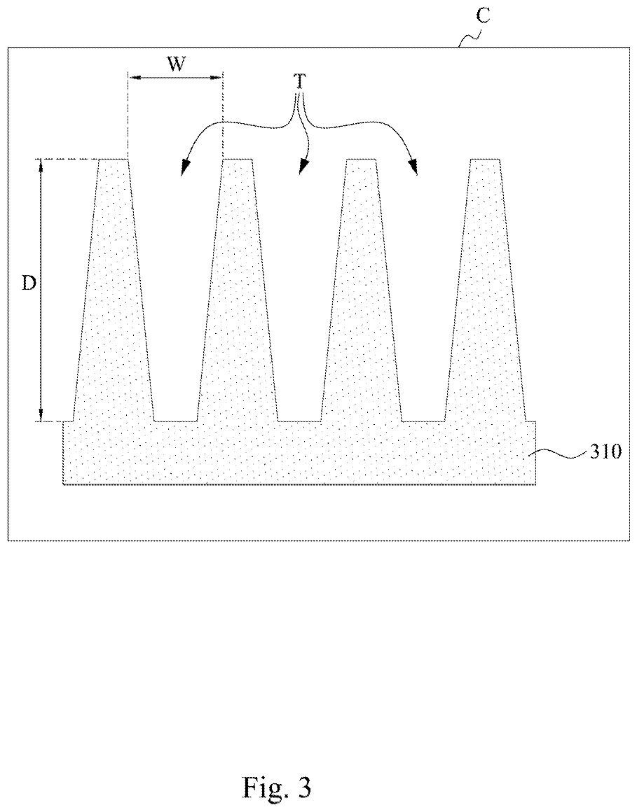

Reference is made to FIG. 3. FIG. 3 is a schematic view of an intermediate stage of manufacturing a semiconductor device 300 in accordance with an embodiment of present disclosure. As shown in FIG. 3, a semiconductor substrate 310 is provided. The semiconductor substrate 310 includes a plurality of trenches T formed on its surface. For example, the semiconductor substrate 310 may be a structure of a word line.

In some embodiments, the trenches T may be formed by an etching process. For example, the trenches T may be formed using dry etching, wet etching, or the like. The present disclosure is not intended to limit the way or method of forming the trenches T on the surface of the semiconductor substrate 310.

In some embodiments, the semiconductor substrate 310 is formed as a fin structure.

In some embodiments, the semiconductor substrate 310 may include a semiconductor material, such as silicon, doped or undoped silicon, or silicon oxide. However, any suitable materials and sizes may be utilized.

In some embodiments, the semiconductor substrate 310 may be formed by any suitable method, for example, CVD (chemical vapor deposition), PECVD (plasma-enhanced chemical vapor deposition), PVD (physical vapor deposition), ALD (atomic layer deposition), PEALD (plasma-enhanced atomic layer deposition), ECP (electrochemical plating), electroless plating, or the like. The present disclosure is not intended to limit the methods of forming the semiconductor substrate 310.

Step S110 and step S120 are described in detail below.

Step S110: depositing a filling material to fill a trench of a substrate, in which the trench has a depth and a width, a ratio of the depth to the width is equal to or greater than about 8 and in which the filling material includes TiN.

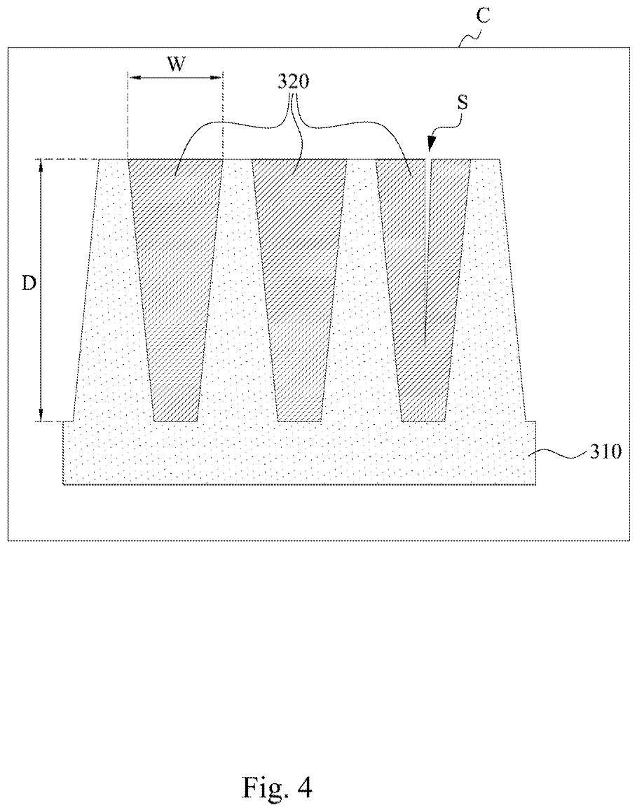

In some embodiments, seams S may be generated in the filling material 320 after step S110 is performed. For example, as shown in FIG. 4, a single seam S is shown included in the filling material 320, but the present disclosure is not limited thereto. The issue of seam-contained filling material 320 may lead to increased resistivity of the semiconductor device 300, thereby deteriorating the electrical performance of the semiconductor device 300.

Step S120: annealing the filling material.

Reference is made to FIGS. 1 and 5. FIG. 5 is a schematic view of an intermediate stage of manufacturing a semiconductor device 300 in accordance with an embodiment of the present disclosure. The semiconductor device 300 includes a filling material 320′ filling the trenches T. As shown in FIG. 5, the filling material 320′ has no seam S after performing the annealing process of step S120 with respect to FIG. 4. The issue of a seam-contained filling material 320 in FIG. 4 may be solved by performing an annealing process to reduce the resistivity of the semiconductor device 300, thereby optimizing the electrical performance of the semiconductor device 300. Specifically, the annealing process is performed to recrystallize the filling material 320, thereby eliminating the seam S included in the filling material 320. This ensures that the resistivity of the semiconductor device 300 can be reduced after performing the annealing process of step S120.

In some embodiments, the annealing process in step S120 is performed in a temperature in a range from about 750 to about 1100 Celsius degree, but the present disclosure is not limited thereto. The present disclosure is not intended to limit the range of the temperature of annealing the filling material 320.

By performing the method 100 shown in FIG. 1 of the present disclosure, the semiconductor device 300 with better electrical performance may be formed.

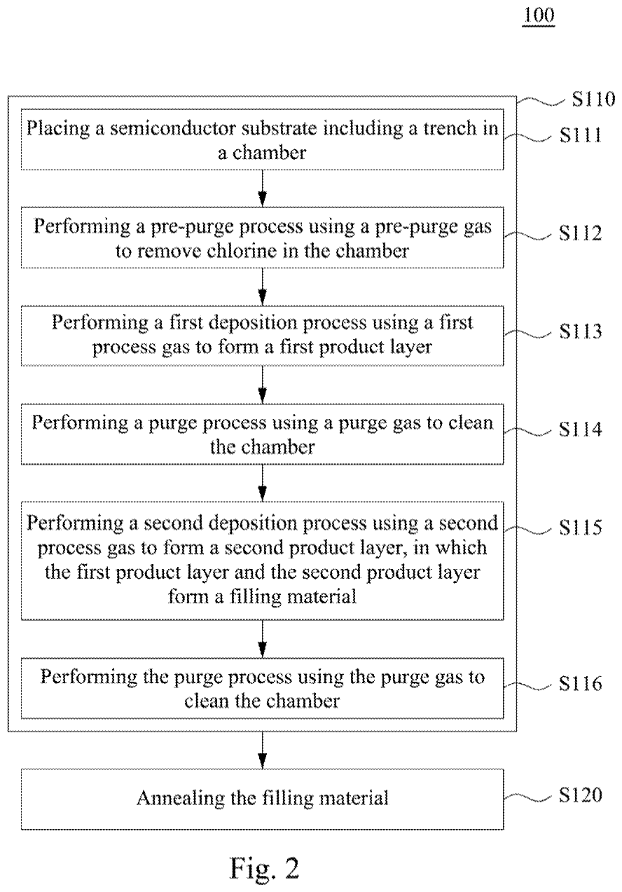

Reference is made to FIG. 2. FIG. 2 is another flow chart of the method 100 of manufacturing the semiconductor device 300 in accordance with an embodiment of present disclosure. As shown in FIG. 2, step S110 further includes step S111, step S112, step S113, step S114, step S115, and step S116. Please refer to FIGS. 2-4 for better understanding steps S111-S116, and refer to FIG. 2 and FIG. 5 for better understanding step S120.

Step S111, step S112, step S113, step S114, step S115, step S116, and step S120 are described in detail below.

Step S111: placing a semiconductor substrate including a trench in a chamber.

Reference is made to FIG. 2. The semiconductor substrate 310 including the trenches T is placed in the chamber C. Each of the trenches T has a depth D and a width W, and a ratio of the depth D to the width W is equal to or greater than about 8. The filling material includes TiN. In some embodiments, as shown in FIG. 3, the width W of each of the trenches T gradually decrease toward the semiconductor substrate 310 (i.e. the width W of each of the trenches T tapers downward to the semiconductor substrate 310), but the disclosure is not limited in this regard.

Step S112: performing a pre-purge process using a pre-purge gas to remove chlorine in the chamber.

Reference is made to FIG. 2. A pre-purge process using the pre-purge gas is performed to remove chlorine in the chamber C. Specifically, the pre-purge process is performed with the pre-purge gas flowed into a chamber C (not shown) to remove the remaining chlorine in the chamber C in previous operations. In this way, the pre-purge process is performed as a precondition step of a subsequent deposition on the semiconductor substrate 310.

In some other embodiments, the step of placing the semiconductor substrate 310 in the chamber C (i.e., step S111) may be performed after the step S112.

In some embodiments, the pre-purge process performed with the pre-purge gas flowed into a chamber C removes about 50% of chlorine by volume in the chamber C. This ensures a high-quality formation of the filling material 320.

In some embodiments, the pre-purge gas includes NH₃ and H₂. NH₃ is included in the pre-purge gas to react with the chlorine compound and remove the chlorine compound from the chamber C. H₂ is included in the pre-purge gas to form high-quality filling material during the subsequent deposition process. Specifically, using a pre-purge gas including H₂ may smooth the grains of a deposited filling material. The pre-purge process using the pre-purge gas may be beneficial to the subsequent deposition process. For example, the resistivity of the semiconductor device 300 may be reduced approximately 55% with performing the pre-purge process of step S112 in the method 100 shown in FIG. 2.

In some embodiments, step S112 may preferably include performing the pre-purge process using NH₃ and H₂, but the present disclosure is not limited thereto. In some other embodiments, step S112 may include performing the pre-purge process using NH₃ only. The present disclosure is not intended to limit the composition of the pre-purge gas used in step S112.

Reference is made to FIGS. 2-4. Steps S113-S116 of the method 100 include depositing a filling material 320 to fill the trenches T of the semiconductor substrate 310. As shown in FIG. 4, a filling material 320 fills the trenches T.

Steps S113-S116 of the method 100 is now respectively described below.

Step S113: performing a first deposition process using a first process gas to form a first product layer.

Reference is made to FIG. 3. The first deposition process is performed with the first process gas flowed into the chamber C to deposit a first product layer (not shown) for forming a part of the filling material 320. For example, the first deposition process is performed as a splitting step of the deposition of the part of the filling material 320 on the semiconductor substrate 310.

In some embodiments, the first process gas used in step S113 includes TiCl₄. For example, TiCl₄ is used as a precursor to form the part of the filling material 320.

In some embodiments, the first product layer may be an ion layer, but the present disclosure is not limited thereto.

In some embodiments, the ion layer formed in step S113 at least includes Ti ions after reacting with TiCl₄.

Step S114: performing a purge process using a purge gas to clean the chamber.

In step S114, the method 100 includes performing the purge process using the purge gas to clean the chamber C. Specifically, the purge process is performed with the purge gas flowed into the chamber C to remove by-products (for example, impurities) produced by the first deposition process from the chamber C.

In some embodiments, the purge gas may include H₂ and N₂. H₂ is included in the purge gas to form high-quality filling material during the subsequent deposition process. Specifically, using the purge gas including H₂ may smooth the grains of deposited filling material 320. Overall, the purge process using the purge gas may be beneficial to the subsequent deposition process.

Step S115: performing a second deposition process using a second process gas to form a second product layer, in which the first product layer and the second product layer form a filling material.

In step S115, the method 100 includes performing the second deposition process using the second process gas. Specifically, the second deposition process is performed with the second process gas flowed into the chamber C to deposit a second product layer (not shown) for forming another part of the filling material 320. More specifically, the second gas flowed into the chamber C to form the second product layer reacting with the first product layer described in step S113, thereby forming a layer of the filling material 320. For example, the second deposition process is performed as a splitting step of the deposition of another part of the filling material 320 on the semiconductor substrate 310.

In some embodiments, the second process gas used in step S115 includes NH₃. For example, NH₃ is used as a precursor to form another part of the filling material 320.

In some embodiments, the second product layer may be another ion layer, but the present disclosure is not limited thereto.

In some embodiments, the another ion layer at least includes N ions after reacting with NH₃.

In some embodiments, the filling material 320 may be composed of TiN which is formed due to homogeneous reaction of the first product layer and the second product layer.

In some embodiments, the filling material 320 may be formed by any suitable method, for example, CVD, PECVD, PVD, ALD, PEALD, ECP, electroless plating, or the like. The present disclosure is not intended to limit the method of forming the filling material 320.

In some embodiments, step S113 and step S115 may be exchanged. For example, the formation of the second product layer in the trenches T may be prior to the formation of the first product layer in the trenches T.

In some embodiments, the first process gas and the second process gas respectively used in step S113 and step S115 may include any suitable material that can form layers of TiN. More specifically, the present disclosure is not intended to limit the types of precursors that can form layers of TiN in steps S113 and S115.

By performing steps S112-S115, a single layer of filling material 320 may be formed. That is to say, the entire filling material 320 may be formed by repeatedly performing steps S112-S115. For example, the user performing steps S112-S115 to deposit the filling material 320 filling the trench T.

Step S116: performing the purge process using the purge gas to clean the chamber.

Next, step S116 is performed. In step S116, the method 100 includes performing the purge process using the purge gas similar or the same as the purge process described in step S114. For example, the purge gas includes H₂ and N₂, which is substantially the same as the purge gas used in step S114. Specifically, the purge process is performed with the purge gas flowed into the chamber C to remove by-products produced by the second deposition process from the chamber C.

Reference is made to FIG. 4. The trenches T are filled with the filling material 320. In some embodiments, some seams S may be generated during the deposition of the filling material 320 of steps S112-S116. For example, as shown in FIG. 4, a single seam S is shown included in the filling material 320, but the present disclosure is not limited thereto. The issue of seam-contained filling material 320 may lead to increased resistivity of the semiconductor device 300, thereby deteriorating the electrical performance of the semiconductor device 300.

In some embodiments, the better example of performing steps S114 and S116 may include performing the purge process using N₂ and H₂, but the present disclosure is not limited to this. In some embodiments, another example of performing steps S114 and S116 may include performing the purge process using N₂ only. The present disclosure is not intended to limit the composition of the purge gas used in steps S114 and S116.

Step S120: annealing the filling material.

In step S120, the method 100 shown in FIG. 2 includes performing the annealing process. As shown in FIG. 5, the trenches T are entirely filled with the annealed filling material 320′. In some embodiments, seams S may be generated in the filling material 320 after step S110 is performed. For example, as shown in FIG. 4, a single seam S is shown included in the filling material 320, but the present disclosure is not limited thereto. The issue of seam-contained filling material 320 may lead to increased resistivity of the semiconductor device 300, thereby deteriorating the electrical performance of the semiconductor device 300. Specifically, the annealing process is performed to recrystallize the filling material 320, thereby eliminating the seam S included in the filling material 320. This ensures that the resistivity of the semiconductor device 300 can be reduced after performing the annealing process of step S120.

Reference is made to FIGS. 2 and 5. FIG. 5 is a schematic view of the semiconductor device 300 processed after performing the annealing process in accordance with an embodiment of the present disclosure. The semiconductor device 300 includes a filling material 320′ filling the trenches T. As shown in FIG. 5, the filling material 320′ has no seam S after performing the annealing process of step S120 with respect to FIG. 4. The issue of seam-contained filling material 320 in FIG. 4 may be solved by performing the annealing process to reduce the resistivity of the semiconductor device 300, thereby optimizing the electrical performance of the semiconductor device 300.

In some embodiments, the annealing process in step S120 in FIG. 2 is performed in a temperature in a range from about 750 to about 1100 Celsius degree, but the present disclosure is not limited thereto. The present disclosure is not intended to limit the range of the temperature of annealing the filling material 320.

In some embodiments, a better example for performing step S112 is performing step S112 before performing steps S113-S120.

By performing the method 100 shown in FIG. 2 of the present disclosure, the semiconductor device 300 with better electrical performance may be formed.

In some embodiments, since the method 100 shown in FIG. 2 includes a pre-purge process and a purge process, the filling material 320 of the semiconductor device 300 formed by the method 100 shown in FIG. 2 has a higher quality than the filling material 320 of the semiconductor device 300 formed by the method 100 shown in FIG. 1.

In some embodiments, the method 100 shown in FIG. 1 and method 100 shown in FIG. 2 are more appropriately used for forming the semiconductor device 300 including the trenches T with a larger aspect ratio. More specifically, for example, each of the trenches T has a depth D and a width W, and a ratio of the depth D to the width W is equal to or greater than about 8, but the present disclosure is not limited thereto.

In some embodiments, the purge process may be performed between the first deposition process and the second deposition process. Alternatively, in some embodiments, the purge process may be performed after the second deposition process. In some embodiments in which the first deposition and the second deposition process are performed repeatedly, the purge process may be performed following the first deposition process or the second deposition process.

In the embodiments of the present disclosure, the method of manufacturing the semiconductor device solves the word line filling problem of the conventional method, so that the semiconductor device has higher quality word lines, thereby reducing resistivity and improving its electrical performance.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of manufacturing a semiconductor device, comprising:
depositing a filling material to fill a trench of a substrate, wherein the trench has a depth and a width, and a ratio of the depth to the width is equal to or greater than 8, and wherein the filling material comprises TiN; and
annealing the filling material.

2. The method of claim 1, wherein the depositing the filling material comprises:
placing the substrate in a chamber;
performing a first deposition process using a first process gas in the chamber; and
performing a second deposition process using a second process gas in the chamber.

3. The method of claim 2, wherein the first process gas comprises TiCl₄.

4. The method of claim 2, wherein the second process gas comprises NH₃.

5. The method of claim 2, further comprising:
performing a purge process using purge gas in the chamber.

6. The method of claim 5, wherein the performing the purge process is after the performing the first deposition process and before the performing the second deposition process.

7. The method of claim 5, wherein the performing the purge process is after the performing the second deposition process.

8. The method of claim 5, wherein the purge gas comprising H₂ and N₂.

9. The method of claim 5, wherein the performing the purge process is before the performing the first deposition process.

10. The method of claim 9, wherein the purge gas comprising NH₃ and H₂.

11. The method of claim 1, wherein the depositing the filling material entirely fills the trench with the filling material.

12. The method of claim 1, wherein the annealing is performed in a temperature in a range from 750 to 1100 Celsius degree.
